(19) United States
(12) Patent Application Publication
(10) Pub. No.: US 2017/0271471 A1
(43) Pub. Date: Sep. 21, 2017

(54) NiPt AND Ti INTERSECTING SILICIDE PROCESS AND STRUCTURE

(71) Applicant: International Business Machines Corporation, Armonk, NY (US)

(72) Inventors: Nicolas L. Breil, Beacon, NY (US); Brett H. Engel, Ridgefield, CT (US); Michael A. Gribelyuk, Stamford, CT (US); Ahmet S. Ozcan, Chappaqua, NY (US)

(21) Appl. No.: 15/615,139

(22) Filed: Jun. 6, 2017

Related U.S. Application Data
(62) Division of application No. 14/988,902, filed on Jan. 6, 2016.

(51) Int. Cl. H01L 29/66; H01L 29/78; H01L 23/535; H01L 29/49; H01L 21/768

(52) U.S. Cl. CPC H01L 29/665; H01L 29/495; H01L 21/76897; H01L 23/535; H01L 29/78

(57) ABSTRACT

A method includes forming a first silicide on a substrate after patterning a gate and spacer onto the substrate. A film is deposited over the substrate. A portion of the dielectric film is removed to expose the first silicide. A portion of the first silicide is removed to form a punch through region. A liner is deposited in the punch through region. A metal layer is deposited on the liner. The substrate is annealed to form a second silicide on the substrate.

### DOMESTIC PRIORITY

The present application is a divisional of U.S. patent application Ser. No. 14/988,902, filed on Jan. 6, 2016, which is hereby incorporated by reference in its entirety.

### BACKGROUND

The present disclosure relates to semiconductor devices and methods for making the semiconductor devices, specifically, the present disclosure relates to semiconductor devices having a first silicide and a second silicide deposited on a semiconductor substrate.

Complementary metal oxide semiconductor (CMOS) is used for constructing integrated circuits. CMOS technology is used in microprocessors, microcontrollers, static RAM, and other digital logic circuits. CMOS designs may use complementary and symmetrical pairs of p-type and n-type metal oxide semiconductor field effect transistors (MOSFETs) for logic functions.

The MOSFET is a transistor used for switching electronic signals. The MOSFET has a source, a drain, and a metal oxide gate electrode. The metal gate is electrically insulated from the main semiconductor n-channel or p-channel by a thin layer of insulating material, for example, silicon dioxide or high dielectric constant (high-k) dielectrics, which makes the input resistance of the MOSFET relatively high. The gate voltage controls whether the path from drain to source is an open circuit (“off”) or a resistive path (“on”).

N-type field effect transistors (nFET) and p-type field effect transistors (pFET) are two types of complementary MOSFETs. The nFET uses electrons as the current carriers and with n-doped source and drain junctions. The pFET uses holes as the current carriers and with p-doped source and drain junctions

High resistance can be associated with source and drain contacts punching through existing silicide layers.

### SUMMARY

According to an embodiment of the present invention, a method comprises forming a first silicide on a substrate after patterning a gate and spacer onto the substrate; depositing a dielectric film over the substrate; removing a portion of the dielectric film to expose the first silicide; removing a portion of the first silicide to form a punch through region; depositing a liner in the punch through region; depositing a metal layer on the liner; and annealing the substrate to form a second silicide on the substrate.

According to another embodiment of the present invention, a method comprises forming a first silicide on a substrate after patterning a gate and spacer onto the substrate, wherein the first silicide comprises nickel silicide, nickel platinum silicide, cobalt di-silicide, or a combination comprising at least one of the foregoing; depositing a dielectric film over the substrate; removing a portion of the dielectric film to expose the silicide; removing a portion of the silicide to form a punch through region; depositing a liner in the punch through region, wherein the liner comprises titanium, titanium nitride, or a combination comprising at least one of the foregoing and wherein the liner has a thickness of 4 to 10 nanometers; depositing a metal layer on the liner, wherein the metal layer comprises tungsten; and annealing to form a second silicide on the substrate, wherein the second silicide comprises titanium silicide.

According to another embodiment of the present invention, a semiconductor device comprises a gate, a spacer, and a substrate, wherein the gate and the spacer are disposed on the substrate; a first silicide on the substrate located between the gate and the spacer; a dielectric film disposed over the substrate; a punch through region in a portion of the dielectric film and the silicide; a liner disposed in the punch region and a metal layer material disposed on the liner; and a second silicide arranged on the substrate underneath the punch through region.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a conceptual diagram of voids formed in source/drain contacts.

FIG. 2 is a cross-sectional illustration of a semiconductor device after a first silicide has been deposited.

FIG. 3 is a cross-sectional illustration of the semiconductor device of FIG. 2 after dielectric film deposition.

FIG. 4 is a cross-sectional illustration of the semiconductor device of FIG. 3 after contact etching and cleaning.

FIG. 5 is a cross-sectional illustration of the semiconductor device of FIG. 4 after liner deposition.

FIG. 6 is a cross-sectional illustration of the semiconductor device of FIG. 5 after filler material has been deposited into the liner.

FIG. 7 is a cross-sectional illustration of the semiconductor device of FIG. 6 after chemical mechanical polishing to remove the linear and filler material from a top surface of the semiconductor device.

FIG. 8 is a cross-sectional illustration of the semiconductor device of claim 7 after annealing to form a second silicide.

### DETAILED DESCRIPTION

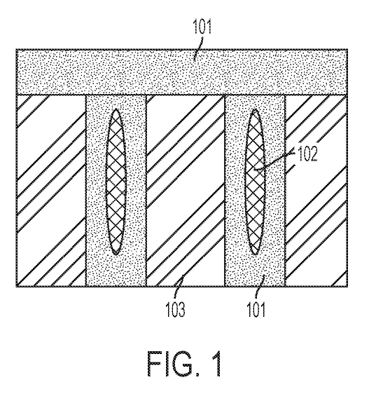

As CMOS devices scale to smaller dimensions, the dimensions of contact widths become smaller. In some devices, titanium nitride (TiN) and tungsten (W) are used to fill contact trenches. However, as shown in FIG. 1, when, for example, chemical vapor deposition (CVD) is used to deposit, for example, tungsten 101, voids 102 or seams may form within trenches between gates 103 that have narrow dimensions. The voids 102 may cause high contact resistance. High contact resistance can cause source and drain contacts to punch through silicide layers and land in higher resistance silicon containing active materials. This issue can stress the contact module reactive ion etching, which can move the process window to a space where the contact suffers from an incomplete etch. The semiconductor devices and methods of making disclosed herein can solve this problem by the formation of a second silicide film to join the first silicide film.

For example, a semiconductor device can utilize post contact reactive ion etching silicide (e.g., TiSi) formation to form silicide under the contact, and bridge the continuity across the “broken” first silicide film. For example, during etching of the contact, overetching can break the first silicide film, which will increase the contact resistance be high. With the method disclosed herein, a post annealing process (e.g., laser spike annealing) can be performed to form a second silicide film under the contact, to lower the resistance and create a conductive silicide bridge under the contact. This can effectively link the first silicide film and the second silicide film.

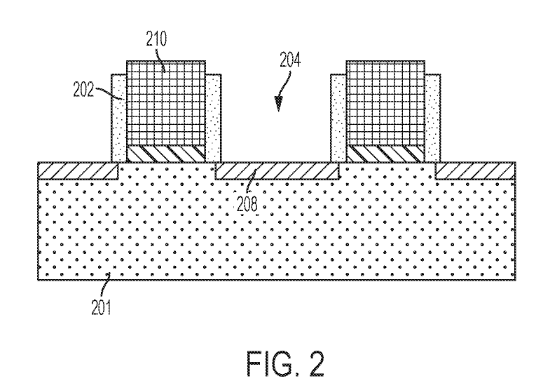

FIGS. 2-8 show exemplary methods of making semiconductor devices according to a first embodiment. FIG. 2 is a cross-sectional side view of a first silicide layer 208 deposited in contacts 204 between gates 210 arranged on a substrate 201. As shown in FIG. 2, spacers 202 can be deposited around gates 210.

The substrate 201 can include one or more semiconductor materials. Non-limiting examples of substrate 201 materials include Si (silicon), strained Si, SiC (silicon carbide), carbon doped silicon (Si:C), Ge (germanium), SiGe (silicon germanium), SiGeC (silicon-germanium-carbon), Si alloys, Ge alloys, III-V materials (e.g., GaAs (gallium arsenide), InAs (indium arsenide), InGaAs (indium gallium arsenide) InP (indium phosphide), or aluminum arsenide (AlAs)), II-VI materials (e.g., CaSe (cadmium selenide), CaS (cadmium sulfide), CaTe (cadmium telluride), ZnO (zinc oxide), ZnSe (zinc selenide), ZnS (zinc sulfide), or ZnTe (zinc telluride)), or a combination comprising at least one of the foregoing. Other examples of substrates 201 include silicon-on-insulator (SOI) substrates and silicon-germanium on insulator substrates with buried dielectric layers.

A source/drain (active region) (not shown) can be formed on the substrate 201 between the gates 210. The source/drain can be formed by an epitaxial growth process or by incorporating a dopant into the substrate 201. The epitaxial layers can be grown using a desirable growth process, for example, chemical vapor deposition (CVD) (liquid phase (LP) or reduced pressure chemical vapor deposition (RPCVD), vapor-phase epitaxy (VPE), molecular-beam epitaxy (MBE), liquid-phase epitaxy (LPE), metal organic chemical vapor deposition (MOCVD), or other processes. The epitaxial growth can include, for example, silicon, silicon germanium, and/or carbon doped silicon (Si:C) silicon, and can be doped during deposition by adding a dopant or impurity to form a first silicide.

The first silicide (also referred to herein as the first silicide layer) can include nickel silicide, nickel platinum silicide, where platinum is present in an amount of 1 to 20%, cobalt di-silicide, or a combination comprising at least one of the foregoing. A thickness of the first silicide can be 5 nanometers (nm) to 25 nm, for example, 10 nm to 20 nm, for example, 15 nm.

The gates 210 can be gate stacks that are formed either by a replacement metal gate process, i.e., replacing a dummy gate (including a sacrificial gate material), or by gate-first process, i.e., directly forming the gates 210 on the substrate 201.

When a replacement metal gate process is used, the dummy gates are filled with a sacrificial material, for example, amorphous silicon (aSi) or polycrystalline silicon (polysilicon). The sacrificial material can be deposited by a deposition process, including, but not limited to, physical vapor deposition (PVD), chemical vapor deposition (CVD), plasma enhanced chemical vapor deposition (PECVD), inductively coupled plasma chemical vapor deposition (ICP CVD), or a combination comprising at least one of the foregoing.

The sacrificial gate material can be replaced with a metal gate stack. The gate stack may include metal gates formed, for example, by filling the dummy gate opening with one or more dielectric materials, one or more workfunction metals, and one or more metal gate conductor materials. The gate dielectric material(s) can be a dielectric material having a dielectric constant greater than 3.9, for example, greater than 7.0. A low-k dielectric material can generally be referred to as having a dielectric constant of less than 4.0. A high-k dielectric material can generally be referred to as having a dielectric constant of greater than 7. Non-limiting examples of materials for the dielectric material include oxides, nitrides, oxynitrides, silicates (e.g., metal silicates), aluminates, titanates, nitrides, or a combination comprising at least one of the foregoing. Examples of low- k dielectric materials (with a dielectric constant of less than 4.0) include, but are not limited to, silicon oxide, silicon nitride, silicon dioxide, spin-on-glass, a flowable oxide, a high density plasma oxide, borophosphosilicate glass (BPSG), or a combination comprising at least one of the foregoing. Examples of high-k materials (with a dielectric constant greater than 7.0) include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate dielectric material layer can be formed by deposition processes, for example, chemical vapor deposition (CVD), plasma-enhanced chemical vapor deposition (PECVD), atomic layer deposition (ALD), evaporation, physical vapor deposition (PVD), chemical solution deposition, or other like processes. The thickness of the dielectric material can vary depending on the deposition process as well as the composition and number of materials used. The gate dielectric material layer can have a thickness in a range from about 0.5 to about 20 nm.

The work function metal(s) may be disposed over the gate dielectric material. The type of work function metal(s) depends on the type of transistor. Non-limiting examples of suitable work function metals include p-type work function metal materials and n-type work function metal materials. P-type work function materials include compositions such as ruthenium, palladium, platinum, cobalt, nickel, and conductive metal oxides, or any combination thereof. N-type metal materials include compositions such as hafnium, zirconium, titanium, tantalum, aluminum, metal carbides (e.g., hafnium carbide, zirconium carbide, titanium carbide, and aluminum carbide), aluminides, or a combination comprising at least one of the foregoing. The work function metal(s) can be deposited by a deposition process, for example, CVD, PECVD, PVD, plating, thermal or e-beam evaporation, and sputtering.

A conductive metal can be deposited over the dielectric material(s) and workfunction layer(s) to form the gate stacks. Non-limiting examples of conductive metals include aluminum (Al), platinum (Pt), gold (Au), tungsten (W), titanium (Ti), or a combination comprising at least one of the foregoing. The conductive metal may be deposited by a suitable deposition process, for example, CVD, PECVD, PVD, plating, thermal or e-beam evaporation, and sputtering. A planarization process, for example, chemical mechanical planarization (CMP), can be performed to polish the surface of the conductive gate metal.

The gates 210 can include a gate cap (not shown) arranged thereon. An insulating hard mask material, for example, silicon nitride (SiN), SiOCN, or SiBCN can be deposited on the gates 210 to form the gate cap. The insulating hard mask material can be deposited using a deposition process, including, but not limited to, PVD, CVD, PECVD, or a combination comprising at least one of the foregoing.

Gate spacers 202 can be arranged along sidewalls of the gates. The gate spacers 202 can include an insulating material, for example, silicon dioxide, silicon nitride, SiOCN, or SiBCN. Other non-limiting examples of materials for the gate spacers 202 can include dielectric oxides (e.g., silicon oxide), dielectric nitrides (e.g., silicon nitride), dielectric oxynitrides, or a combination comprising at least one of the foregoing. The gate spacer 202 material can be deposited by a deposition process, for example, chemical vapor deposition (CVD) or physical vapor deposition (PVD).

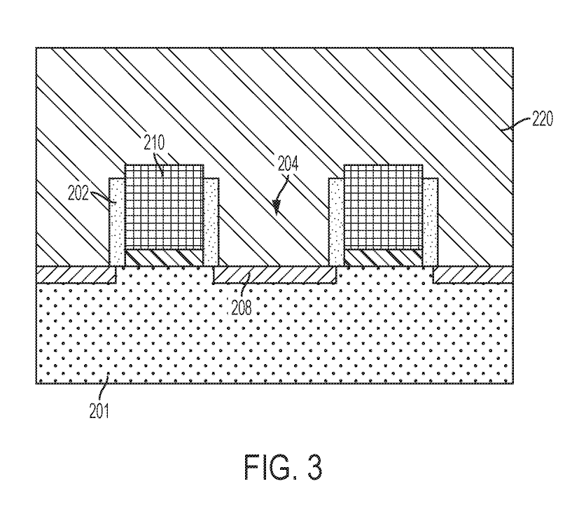

As shown in FIG. 3, a dielectric film 220 can be deposited on, around and between the gates 210. The dielectric film 220 can be formed from, for example, a low-k dielectric material (with k<4.0), including but not limited to, silicon oxide, silicon nitride, silicon dioxide, spin-on-glass, a flowable oxide, a high density plasma oxide, borophosphosilicate glass (BPSG), or a combination comprising at least one of the foregoing. The dielectric film 220 can be deposited by a deposition process, including, but not limited to CVD, PVD, plasma enhanced CVD, atomic layer deposition (ALD), evaporation, chemical solution deposition, or like processes. The dielectric film can have a thickness of 50 to 1,000 nm, for example, 100 to 800 nm, for example, 200 to 750 nm.

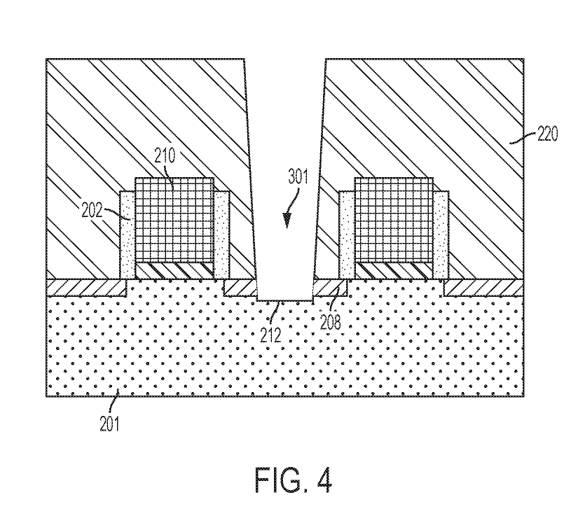

The dielectric film 220 can be removed between the gates to form trenches 301 as shown in FIG. 4. The trenches 301 can be formed over the source/drain regions and form source/drain contact trenches between the gates 210.

To remove the dielectric film 220 and form the trenches 301, a resist, such as a photoresist, may be deposited and patterned. An etch process, such as a reactive ion etch (ME), can be performed using the patterned resist as an etch mask to remove the dielectric film 220 until the source/drain or substrate 201 is exposed. Then the resist may be removed by, for example, ashing. Overetching 212 can be performed as illustrated in FIG. 4, to break through first silicide layer 208.

The trenches 301 can be high aspect ratio trenches, for example, having an aspect ratio (height/width) of at least 4. In some embodiments, the trenches 301 can have a width of 10 to 30 nm, and a height of 30 to 80 nm. In other embodiments, the trenches 301 have a width of 10 to 20 nm, and a height of 50 to 70 nm.

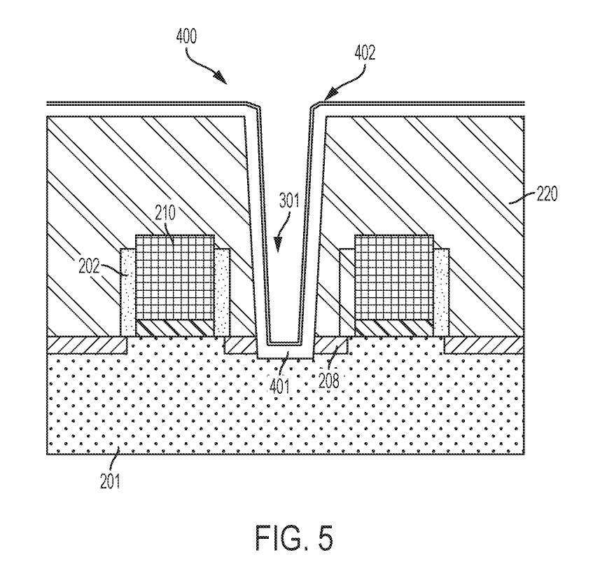

FIG. 5 is a cross-sectional side view after depositing a liner 400 comprising a base portion 401 and an inner portion 402 in the trench 301. The liner 401 material depends on the type of transistor and can include one or more materials that provide low contact resistance. The liner 400 can include one or more layers or films that may be formed in separate reaction chambers or in an integrated reaction chamber. Non-limiting examples of materials for the liner 400, including the base portion 401 and the inner portion 402, include Co, Ti, CoTi, Ni, Pt, NiPt, NiPtTi, Ta, TaNi, TaAl, TaAlN, TiN, TiAl, TiAlN, or a combination comprising at least one of the foregoing. The one or more layers/films making up the liner 400 may be formed by a chemical vapor deposition process (CVD), plasma vapor deposition (PVD), radio frequency plasma vapor deposition (REPVD), atomic layer deposition (ALD), or other desirable process.

The thickness of the liner base portion 401 can generally vary and is not intended to be limited. For example, the thickness of the liner base portion 401 can be 0.5 to 15 nm, for example, 2 to 12 nm, for example, 4-10 nm, for example, 12 nm. The thickness of the liner inner portion 402 can be 1 to 15 nm, for example, 1.5 to 10 nm, for example, 2 to 5 nm, for example, 3 nm.

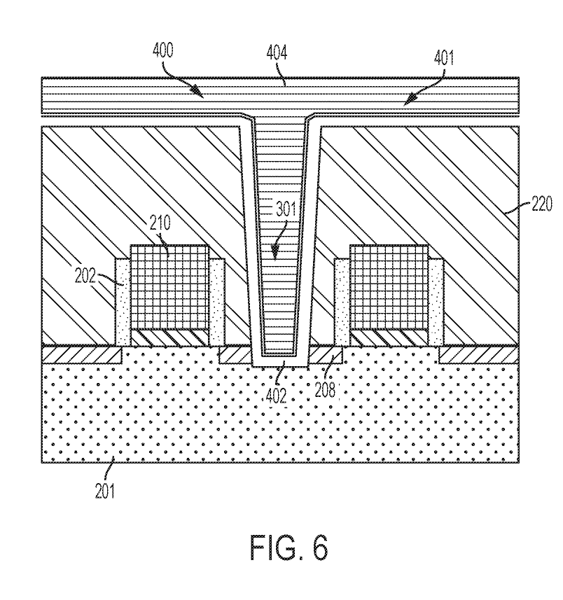

A metal layer 404 can be deposited on the liner 400 within the trench 301 as shown in FIG. 6, but the majority of the metal is deposited on the surface of the deposition layer 220 and on the gates caps. The metal layer 404 can be, but is not limited to, cobalt, tungsten, copper, aluminum, titanium, or a combination comprising at least one of the foregoing.

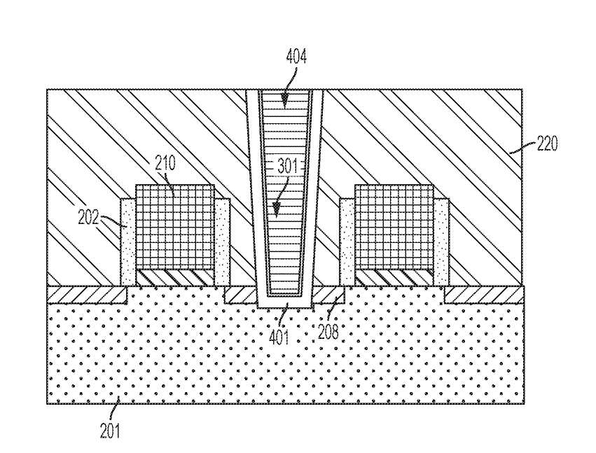

A CVD, PVD, ALD, or like processes can be used to deposit the metal layer 404. The CVD method used to form the metal layer 404 uses a physical process to deposit the material from a target film in a single deposition step. Although some metal is deposited in the trench 301, a majority of the metal is deposited on the surface of the gate caps and the dielectric layer 220. As discussed below in FIG. 7, a heat treatment (anneal) can be performed to heat the metal layer 404, to reflow the deposited metal into the trench 301.

Generally, CVD methods used to deposit metal can only form a thin film along sidewall surfaces and may not completely fill a trench contact. If more metal is deposited into the trench, the deposited metal may form a seam or void within the trench (see FIG. 1). Such CVD methods that result in seams in contact trenches may use more than a 400 Watt (W) bias to maximize deposition conformity, i.e., feature/sidewall coverage.

The amount to metal deposited can generally vary and depends on the dimensions of the trench 301. Enough metal should be deposited on the surface of the dielectric layer 220 and gates 210 to fill the trenches 301 after heating to reflow the metal. In some embodiments, the thickness of the metal layer 404 on the surface of gates 210 is 2 to 100 nm, for example, 5 to 75 nm, for example, 25 to 50 nm.

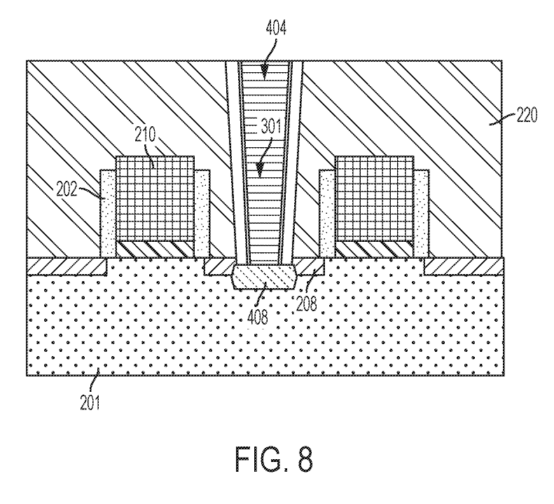

FIG. 7 is a cross-sectional side view of an embodiment after chemical mechanical polishing (CMP) to remove the liner and metal layer from a top surface. As shown in FIG. 7, metal layer 404 is present in trench 301. FIG. 8 shows heating to reflow the deposited metal layer 404 into the trench 301. The metal substantially fills the trench 301 and forms a high aspect ratio metal containing contact without seams/voids. The aspect ratio is determined by dividing the height by the width. The contacts described herein have aspect ratios of at least 3 or 3 to 8. In an embodiment, annealing can be completed after deposition of liner 400, before chemical mechanical polishing.

Heating to reflow the metal may be an anneal process performed by heating the wafer inside a furnace or performing a rapid thermal treatment in an atmosphere containing pure inert gases (e.g., nitrogen or argon). The anneal process may be, for example, a Rapid Thermal Anneal (RTA) or Rapid Thermal Processing (RTP). Heating may be performed in the same chamber as the metal deposition or in a different chamber than the metal deposition.

In some embodiments, the heating/anneal process is performed at a temperature of 600 to 900° C. for 0.1 to 10 milliseconds, for example, 0.1 to 4 milliseconds. In other embodiments, the heating/anneal process is performed at a temperature of 400 to 600° C. for 1 to 30 seconds, for example, 2 to 25 second, for example, 5 to 20 seconds.

It will also be understood that when an element, such as a layer, region, or substrate is referred to as being “on” or “over” another element, it can be directly on the other element or intervening elements may also be present. In contrast, when an element is referred to as being “directly on” or “directly over” another element, there are no intervening elements present, and the element is in contact with another element.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the articles “a” and “an” preceding an element or component are intended to be nonrestrictive regarding the number of instances (i.e. occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a gate, a spacer, and a substrate, wherein the gate and the spacer are disposed on the substrate;
a first silicide on the substrate located between the gate and the spacer;
a dielectric film disposed over the substrate;
a punch through region in a portion of the dielectric film and the silicide;
a liner disposed in the punch region and a metal layer material disposed on the liner; and
a second silicide arranged on the substrate underneath the punch through region.

2. The semiconductor device of claim 1, wherein the substrate comprises silicon, silicon germanium, silicon carbide, indium gallium arsenide, gallium arsenide, or a combination comprising at least one of the foregoing.

3. The semiconductor device of claim 1, wherein the substrate comprises a silicon on insulator substrate with a buried dielectric layer.

4. The semiconductor device of claim 1, wherein the substrate comprises a silicon- germanium on insulator substrate with a buried dielectric layer.

5. The semiconductor device of claim 1, wherein the first and/or second silicide materials comprise nickel silicide, nickel platinum silicide, cobalt di-silicide, titanium silicide, titanium nitride silicide, or a combination comprising at least one of the foregoing.

6. The semiconductor device of claim 5, wherein the first silicide comprises nickel platinum silicide, wherein platinum is present in an amount of 1 to 20%.

7. The semiconductor device of claim 6, wherein the first silicide and/or the second silicide have a thickness of 10 to 25 nanometers.

8. The semiconductor device of claim 7, wherein the thickness is 15 nanometers.

9. The semiconductor device of claim 1, wherein the dielectric film comprises at least one layer.

10. The semiconductor device of claim 1, wherein the dielectric film comprises a nitride, an oxide, or a combination comprising at least one of the foregoing.

11. The semiconductor device of claim 1, wherein the dielectric film has a thickness of 100 to 800 nanometers.

12. The semiconductor device of claim 1, wherein the liner comprises a base portion and an inner portion.

13. The semiconductor device of claim 13, wherein the base portion comprises Co, Ti, CoTi, Ni, Pt, NiPt, NiPtTi, Ta, TaNi.

14. The semiconductor device of claim 13, wherein the inner portion comprises Co, Ti, CoTi, Ni, Pt, NiPt, NiPtTi, Ta, TaNi.

15. The semiconductor device of claim 13, wherein the base portion comprises a metal and the inner portion comprises a nitride.

16. The semiconductor device of claim 1, wherein the base portion has a thickness of 2 to 12 nanometers and the inner portion has a thickness of 2 to 5 nanometers.

17. The semiconductor device of claim 16, wherein the base portion thickness of 4 to 10 nanometers.

18. The semiconductor device of claim 16, wherein the inner portion has a thickness of 3 nanometers.

19. The semiconductor device of claim 1, wherein the metal layer comprises tungsten.

20. The semiconductor device of claim 19, wherein the second silicide comprises a low resistance silicide.
